(19) United States
(12) Patent Application Publication
(10) Pub. No.: US 2008/0042223 A1
(43) Pub. Date: Feb. 21, 2008

(54) MICROELECTROMECHANICAL SYSTEM PACKAGE AND METHOD FOR MAKING THE SAME

(76) Inventors: Lu-Lee Liao, Taichung (TW); Hong-Ching Her, Taichung (TW); Shih-Chin Gong, Taichung (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/465,249

(22) Filed: Aug. 17, 2006

(51) Int. Cl. H01L 29/84

(52) U.S. Cl. 257/415

(57) ABSTRACT

A microelectromechanical system package includes a substrate, a microelectromechanical system transducer mounted on the substrate by a plurality of metal bumps, a non-conductive polymer ring provided around the microelectromechanical transducer for avoiding the leakage of sound pressure from the microelectromechanical transducer, an integrated circuit mounted on the substrate by a plurality of metal bumps for matching the impedance of the microelectromechanical system transducer or amplifying the electric signals and an electrically conductive bridge for electrically connecting the integrate circuit to the substrate.

### BACKGROUND OF INVENTION

1. FIELD OF INVENTION

The present invention relates to a microelectromechanical system package and a method for making the same. More particularly, this invention relates to a microelectromechanical system condenser microphone. The microelectromechanical microphone must be packaged to function properly.

2. RELATED PRIOR ART

Disclosed in U.S. Pat. No. 6,781,231 is a microelectromechanical system package 10 including a substrate 14, a plurality of components 12 mounted on the substrate 14 and a cover 20 installed on the substrate 14 for covering the components 12. The cover 20 consists of an external cup 25a and an internal cup 25b installed within the external cup 25a. The cover 20 is used to protect physical damage, light, and electromagnetic interference. The cover 20 and the substrate 14 define a housing 22. The cover 20 includes a plurality of acoustic ports 44 each including an environmental barrier layer 48. The microelectromechanical system package 10 is too heavy and bulky for including the cover 20.

The present invention is therefore intended to obviate or at least alleviate the problems encountered in prior art.

### SUMMARY OF INVENTION

According to the present invention, a microelectromechanical system package includes a substrate, a microelectromechanical transducer mounted on the substrate by a plurality of metal bumps, a non-conductive polymer ring provided around the microelectromechanical transducer for avoiding the leakage of sound pressure from the microelectromechanical transducer, an integrated circuit installed on the substrate by a plurality of metal bumps for matching the impedance of electric signals or amplifying the electric signals and an electrically conductive bridge for electrically connecting the integrate circuit to the substrate.

According to the present invention, there is provided a method for making a microelectromechanical system package. In the method, a substrate is provided. A solder pad is provided on the substrate by a screen printing technique. Provided on the substrate are a microelectromechanical system transducer with a plurality of metal bumps and an integrated circuit with a plurality of metal bump. The substrate, the microelectromechanical system transducer and the integrated circuit are subjected to a reflow process in a reflow oven. A non-conductive polymer ring is provided around the microelectromechanical system transducer. An electrically conductive bridge is provided for electrically connecting the integrated circuit to the substrate. The substrate, the microelectromechanical system transducer and the integrated circuit are subjected to a curing process.

The primary advantage of the microelectromechanical system package according to the present invention is the protection from electromagnetic interference and the reduction of the size are achieved without having to provide an intermediate PCB for forming a cover.

Other advantages and features of the present invention will become apparent from the following description referring to the drawings.

### BRIEF DESCRIPTION OF DRAWINGS

The present invention will be described through detailed illustration of five embodiments referring to the drawings.

FIG. 1 is a cross-sectional view of a microelectromechanical system package according to the first embodiment of the present invention.

FIG. 2 is a cross-sectional view of a microelectromechanical system package according to the second embodiment of the present invention.

FIG. 3 is a cross-sectional view of a microelectromechanical system package according to the third embodiment of the present invention.

FIG. 4 is a cross-sectional view of a microelectromechanical system package according to the fourth embodiment of the present invention.

FIG. 5 is a cross-sectional view of a microelectromechanical system package according to the fifth embodiment of the present invention.

### DETAILED DESCRIPTION OF EMBODIMENTS

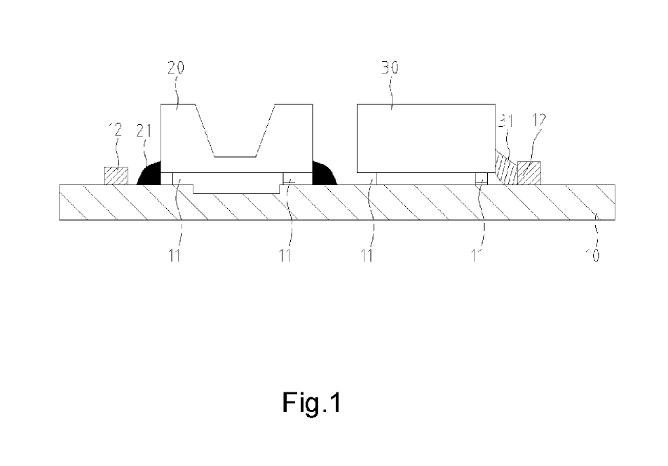

Referring to FIG. 1, there is shown a microelectromechanical system (“MEMS”) package including a substrate 10, a MEMS transducer 20 mounted on the substrate 10 and an integrated circuit 30 (“IC 30”) mounted on the substrate 10. The substrate 10 is a printed circuit board (“PCB”) or a ceramic substrate. The MEMS transducer 20 is used to convert sound pressure into electrical signals. The IC 30 is used to match the impedance of the MEMS transducer or amplifying the electrical signals.

The substrate 10 is provided with a solder ring 12 along the edge thereof. The solder ring 12 is used to reduce electromagnetic interference. So are noises that affect the quality of the sound pressure received by the MEMS transducer 20. The solder ring 12 may be provided by a screen printing technique and grounded.

The substrate 10 is provided with a non-conductive polymer ring 21 around the MEMS transducer 20. The non-conductive polymer ring 20 is used to prevent leakage of the sound pressure from the MEMS transducer 20 to the substrate 10. Thus, the sensitivity of the receipt of the sound pressure is improved.

The MEMS transducer 20 is provided with many metal bumps 11 corresponding to a plurality of predetermined spots on the substrate 10 so that the MEMS transducer 20 can be mounted on the substrate by a flip chip technique. The flip chip technique not only reduces the distance of the transmission of electric signals between the MEMS transducer 20 and the substrate 10 but also reduces the size of the microelectromechanical system. The metal bumps 11 are preferably solder bumps.

The IC 30 is provided with many metal bumps 11 corresponding to a plurality of predetermined spots on the substrate 10 so that the IC 30 can be mounted on the substrate by the flip chip technique.

There is provided an electrically conductive bridge 31 for electrically connecting the IC 30 to the solder ring 20 so that the IC 30 is grounded. The electrically conductive bridge 31 is preferably non-conductive polymer. Alternatively, the IC 30 may be installed on the solder ring 12 directly so that the IC 30 is grounded.

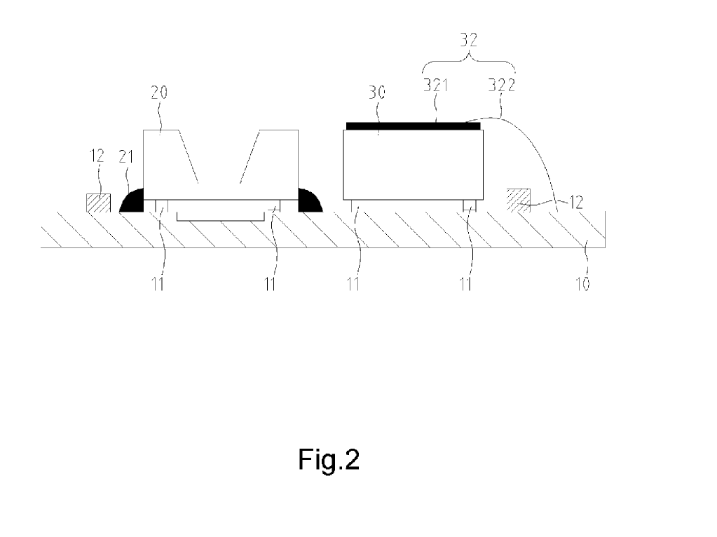

Referring to FIG. 2, there is shown a microelectromechanical system package according to a second embodiment of the present invention. The second embedment is like the first embodiment except including an electrically conductive bridge 32 instead of the electrically conductive bridge 31. The electrically conductive bridge 32 includes an electrically conductive layer 321 installed on the IC 30 and an electrically conductive wire 322 for electrically connecting the electrically conductive layer 321 to the substrate 10.

The electrically conductive layer 321 may be provided on the IC 30 by the screen printing technique or a metal film coating technique. The electrically conductive wire 322 may be provided between the electrically conductive layer 321 and the substrate 10 by a wire bond technique. The electrically conductive wire 322 may be a gold or aluminum wire. Thus, grounding is done and the size of the microelectromechanical system is reduced.

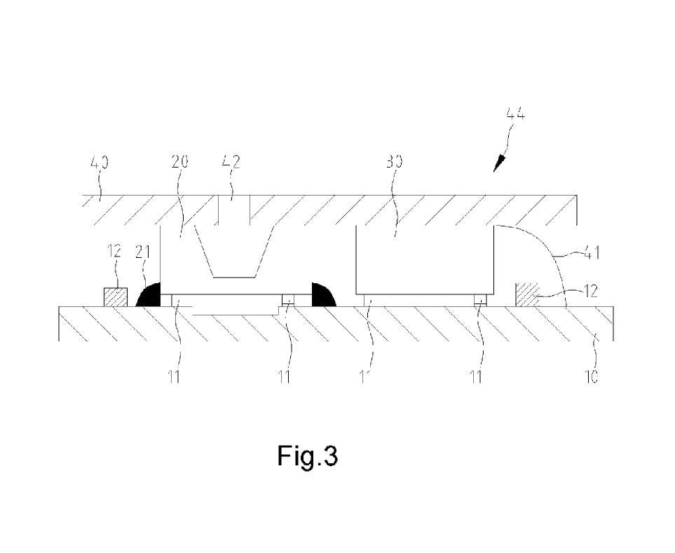

Referring to FIG. 3, there is shown a microelectromechanical system package according to a third embedment of the present invention. The third embodiment is like the second embodiment except including an electrically conductive bridge 44 instead of the electrically conductive bridge 32. The electrically conductive bridge 44 includes a lid 40 and an electrically conductive wire 41. The lid 40 is installed on the MEMS transducer 20 and the IC 30. The electrically conducive wire 41 is used to electrically connect the lid 40 to the substrate 10 so that grounding is done. The electrically conductive wire 41 may be provided by the wire bond technique. Alternatively, the lid 40 may be electrically connected to the substrate 10 by a gluing technique. Thus, the size of the MEMS package is reduced. The lid 40 defines an acoustic aperture 42 corresponding to the MEMS transducer 20. Via the acoustic aperture 42, the MEMS transducer 20 converted sound pressure into electrical signals by the same.

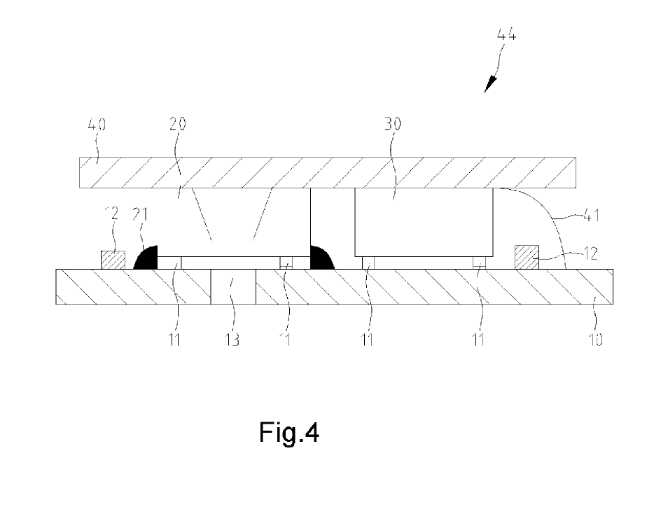

Referring to FIG. 4, there is shown a microelectromechanical system package according to a fourth embedment of the present invention. The fourth embodiment is like the third embodiment except an acoustic aperture 13 is defined in the substrate 10 instead of the acoustic aperture 42 defined in the lid 40. The acoustic aperture 13 is located corresponding to the MEMS transducer 20. Through the acoustic aperture 13, sound pressure is sent to the MEMS transducer 20 and converted into electric signals by the same.

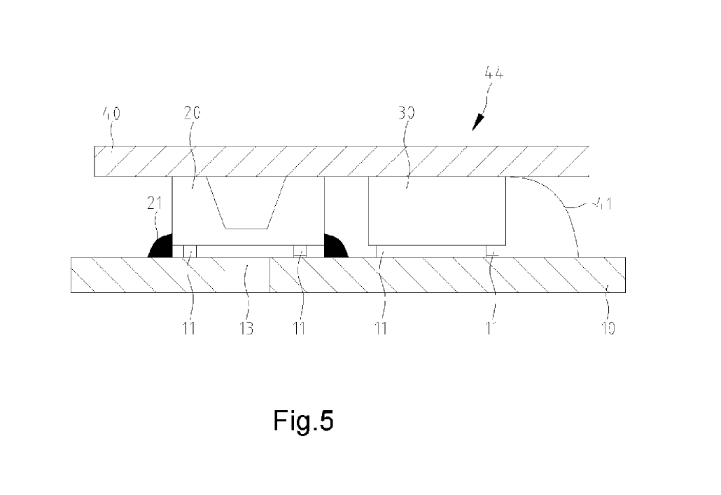

Referring to FIG. 5, there is shown a microelectromechanical system package according to a fifth embedment of the present invention. The fifth embodiment is like the fourth embodiment except eliminating the solder ring 12. Thus, a step is omitted during the packaging of the microelectromechanical system. The fifth embodiment can be used in an environment or product where the electromagnetic interference is low.

Moreover, according to the present invention, here is provided a method for packaging the microelectromechanical system. In the method, the substrate 10 is provided.

A solder pad is provided on the substrate 10 by a screen printing technique.

A solder ring 12 may be provided on and around the substrate 10 by the screen printing technique.

The MEMS transducer 20 is provided with the metal bumps 11, and the IC 30 is provided with the metal bumps 11.

The MEMS transducer 20 and the IC 30 are temporarily provided on the solder pad by solder paste.

The substrate 10, the MEMS transducer 20 and the IC 30 are subject to a reflow process in a reflow oven so that the solder bumps 11 become contact points between the MEMS transducer 20 and the substrate 10 and between the IC 30 and the substrate 10.

The electrically insulating ring 21 is provided around the MEMS transducer 20 by providing a plurality of non-conductive polymer dots, and the electrically conductive bridge 31, 32 or 44 is provided between the IC 30 and the substrate 10.

The electrically conductive bridge 31 may be provided by providing a non-conductive polymer dot.

The electrically conductive bridge 32 may be provided by coating, sputter, deposition, or plating the IC 30 with the electrically conductive layer 321 and electrically connecting the electrically conductive layer 321 to the substrate 10 by providing the electrically conductive wire 322. The electrically conductive wire 322 is provided by the wire bond technique.

The electrically conductive bridge 44 may be provided by providing a lid 40 on the MEMS transducer 20 and the IC 30 and electrically connecting the lid 40 to the substrate 10 by providing the electrically conductive wire 41. The electrically conductive wire 41 is provided by the wire bond technique. The acoustic aperture 42 may be made in the lid 40. Instead of the acoustic aperture 42 defined in the lid 40, the acoustic aperture 13 may be defined in the substrate 10.

The substrate 10, the MEMS transducer 20 and the IC 30 are subjected to a curing process to remove moisture and organic gases.

The microelectromechanical system according to the present invention exhibits several advantages. Firstly, there is no need to provide a cover for housing the components, thus reducing the size of the microelectromechanical system.

Secondly, the solder ring 12 protects the components from electromagnetic interference (“EMI”) or radio frequency (“RF”) interference.

Thirdly, the protection from the electromagnetic interference and the reduction of the size are achieved without having to provide an intermediate PCB for forming a cover required by the prior art.

The present invention has been described through the illustration of the embodiments. Those skilled in the art can derive variations from the embodiments without departing from the scope of the present invention. Therefore, the embodiments shall not limit the scope of the present invention defined in the claims.

What is claimed is:

1. A microelectromechanical system package comprising:
a substrate;
a microelectromechanical transducer mounted on the substrate by a plurality of metal bumps;
a non-conductive polymer ring provided around the microelectromechanical transducer for avoiding the leakage of sound pressure from the microelectromechanical transducer;
an integrated circuit mounted on the substrate by a plurality of metal bumps for matching the impedance of the micromechanical system transducer or amplifying the electrical signals; and
an electrically conductive bridge for electrically connecting the integrate circuit to the substrate.

2. The microelectromechanical system package according to claim 1 wherein the electrically conductive bridge is made of electrically conductive polymer material.

3. The microelectromechanical system package according to claim 1 wherein the electrically conductive bridge comprises an electrically conductive layer on the backside of the integrated circuit and an electrically conductive wire with an end connected to the electrically conductive layer and another end connected to the substrate.

4. The microelectromechanical system package according to claim 1 wherein the electrically conductive bridge comprises a lid mounted on the microelectromechanical transducer and the integrated circuit and an electrically conductive wire with an end connected to the lid and another end connected to the substrate so that the lid is grounded.

5. The microelectromechanical system package according to claim 4 wherein the lid comprises an acoustic aperture defined therein corresponding to the microelectromechanical system transducer so that sound pressure can reach the microelectromechanical transducer through the acoustic aperture.

6. The microelectromechanical system package according to claim 4 wherein the substrate comprises an acoustic aperture defined therein corresponding to the microelectromechanical transducer so that sound pressure can reach the microelectromechanical transducer through the acoustic aperture.

7. The microelectromechanical system package according to claim 6 wherein the electrically conductive wire is made of gold or aluminum.

8. The microelectromechanical system package according to claim 1 comprising a solder ring around the substrate for reducing electromagnetic interference, thus protecting the receipt of sound pressure by the microelectromechanical transducer from noises.

9. The microelectromechanical system package according to claim 1 wherein the substrate is a printed circuit board or a ceramic board.

10. The microelectromechanical system package according to claim 1 wherein the metal bumps are solder bumps or gold bumps.

11. A method for making a microelectromechanical system package comprising the steps of:
providing a substrate;
providing a solder pad on the substrate by a screen printing technique;
providing, on the substrate, a microelectromechanical system transducer with a plurality of metal bumps and an integrated circuit with a plurality of metal bumps;
subjecting the substrate, the microelectromechanical system transducer and the integrated circuit to a reflow process in a reflow oven;
providing a non-conductive polymer ring around the microelectromechanical transducer;
providing an electrically conductive bridge for electrically connecting the integrated circuit to the substrate; and
subjecting the substrate, the microelectromechanical system transducer and the integrated circuit to a curing process.

12. The method according to claim 11 wherein the step of providing an electrically conductive bridge comprises the step of providing a polymer dot between the integrated circuit and the substrate.

13. The method according to claim 11 wherein the step of providing an electrically conductive bridge comprises the step of providing an electrically conductive layer on the integrated circuit and the step of electrically connecting the electrically conductive layer to the substrate by providing the electrically conductive wire.

14. The method according to claim 13 wherein the electrically conductive wire is provided by a wire bond technique.

15. The method according to claim 11 wherein the step of providing an electrically conductive bridge comprises the step of providing a lid on the microelectromechanical system transducer and the integrated circuit and the step of electrically connecting the lid to the substrate by providing an electrically conductive wire.

16. The method according to claim 15 wherein the electrically conductive wire is provided by the wire bond technique.

17. The method according to claim 15 wherein the step of providing the lid comprises the step of making an acoustic aperture in the lid corresponding to the microelectromechanical system transducer.

18. The method according to claim 15 wherein the step of providing the substrate comprises the step of making an acoustic aperture in the substrate corresponding to the microelectromechanical system transducer.

19. The method according to claim 11 wherein the step of providing a solder pad comprises the step of providing a solder ring on and around the substrate by a screen printing technique.
